(19) United States
(12) Patent Application Publication
(10) Pub. No.: US 2022/0123724 A1
(43) Pub. Date: Apr. 21, 2022

(54) ELECTRO ACOUSTIC COMPONENT, RF FILTER AND METHOD OF MANUFACTURING

(71) Applicant: RF360 EUROPE GMBH, Munchen (DE)

(72) Inventor: Konstantin MOGILEVSKY, München (DE)

(21) Appl. No.: 17/425,685

(22) PCT Filed: Jan. 23, 2020
(86) PCT No.: PCT/EP2020/051664

§ 371 Date: Jul. 23, 2021

(30) Foreign Application Priority Data
Feb. 4, 2019 (DE) 10 2019 102 694.6

(51) Int. Cl. H03H 9/17; H03H 3/02; H03H 9/56; H03H 9/13; H03H 9/05

(52) U.S. Cl. CPC H03H 9/175; H03H 3/02; H03H 2003/025; H03H 9/131; H03H 9/0514; H03H 9/568

(57) ABSTRACT

Electro acoustic component, comprising—a carrier substrate (CS), —a first layer stack (BAWR) on or above the carrier substrate, —a second layer stack (EC) on or above the carrier substrate, wherein—the first layer stack comprises a first functional structure (IL) and a second functional structure (TE, BM, PE) arranged on or above the first functional structure, —the second layer stack comprises a raising structure (RS) and a third functional structure (BU, UBM, B) arranged on or above the raising structure, —the raising structure raises the third functional structure to the vertical level of the second functional structure.

The present invention refers to electro acoustic components, specifically to components with an improved electrical contact. Further, the invention refers to corresponding RF filters and methods of manufacturing such components.

RF filters can be used in wireless communication equipment, e.g. in mobile terminals, to separate wanted RF signals from unwanted RF signals. RF filters can comprise electro acoustic components such as electro acoustic resonators. In an electro acoustic resonator an electrode structure is coupled to a piezoelectric material. Due to the piezoelectric effect an electro acoustic resonator converts between electromagnetic RF signals and acoustic RF signals. Corresponding electro acoustic resonators can have a stacked construction with a plurality of two or more layers arranged one above the other.

An electro acoustic component can comprise an electro acoustic resonator and further circuit elements, e.g. active or passive circuit elements and/or connection means for electrically connecting the electro acoustic resonator to an external circuit environment.

What is generally desired is an improved electro acoustic component, i.e. an electro acoustic component with an improved electric and/or acoustic performance.

To that end, an electro acoustic component, an RF filter and a method of manufacturing an electro acoustic component according to the claims are provided. Dependent claims provide preferred embodiments.

The electro acoustic component comprises a carrier substrate, a first layer stack and a second layer stack. The first layer stack is arranged on or above the carrier substrate. The second layer stack is arranged on or above the carrier substrate. The first layer stack comprises a first functional structure. Further, the first layer stack comprises a second functional structure arranged on or above the first functional structure. Further, the second layer stack comprises a raising structure and a third functional structure. The third functional structure is arranged on or above the raising structure. The raising structure raises the third functional structure to the vertical level of the second functional structure.

The carrier substrate establishes a common carrier for the first layer stack and the second layer stack. The first layer stack and the second layer stack can be arranged one next to another on the carrier substrate. The first layer stack and the second layer stack can be arranged directly adjacent to one another. However, it is also possible that a certain distance is arranged between the first layer stack and the second layer stack. Further layer stacks can be arranged—in a horizontal direction—between the first layer stack and the second layer stack.

The first functional structure is a functional structure of the electro acoustic component. The functional structure can establish an electric functionality and/or an acoustic functionality.

Further, the second functional structure can establish an electric and/or an acoustic functionality of the electro acoustic component. Similarly, the third functional structure can establish an electric functionality and/or an acoustic functionality.

The terms “on” or “above” are valid for an orientation of the electro acoustic component where the carrier substrate is below the first and the second layer stack. The vertical level of the third functional structure and the vertical level of the second functional structure refers to the vertical distance between the third and the second, respectively, functional structure and the carrier substrate. Thus, the raising structure is responsible for arranging the bottom portion of the third functional structure at the vertical position of the bottom portion of the second functional structure. Thus, the bases of the second functional structure and of the third functional structure have the height position with respect to the carrier substrate.

Typical attempts to improve an electro acoustic component's performance refer to improving the electro acoustic resonator's performance. However, it was observed that improved components can be obtained when also the electrical connection to an external circuit environment is improved. By positioning the second functional structure and the third functional structure at a common vertical position, the electric connection to an external circuit environment can be improved, especially when the first layer stack and the second layer stack comprise a plurality of stacked layers.

Corresponding layer stacks can comprise a plurality of two or more layers, the materials of which are provided utilizing layer deposition techniques, structuring techniques and—at least partially—material removal techniques. Specifically, levelling steps such as polishing steps can be used to provide a surface of one type of material on which another type of material, e.g. for another layer, should be deposited. For example during manufacturing of a BAW resonator stack (BAW=bulk acoustic wave), an under polish step to prepare the material under a bottom electrode of the resonator may be provided. The polishing step may be a CMP step (CMP=chemical mechanical polish).

By providing the raising structure below the third functional structure it is possible to obtain a vertical position of the top portion of the third functional structure such that the top portion of the third functional structure can have an improved interconnection to an external circuit environment.

Specifically, it is possible to prevent—by providing the raising structure—a remaining dielectric material on a contact pad via which the electro acoustic component should be electrically connected to an external circuit environment.

It is possible that the first functional structure comprises an element of an acoustic mirror. Further, it is possible that the second functional structure comprises an element of an electro-acoustical resonator. The raising structure can comprise an element of a dummy acoustic mirror.

Thus, it is possible that in the first layer stack an electro acoustic resonator, e.g. a BAW resonator is realized. The BAW resonator can comprise an active structure and an acoustic mirror. The active structure can be used to excite acoustic waves. The acoustic mirror can be used to confine acoustic energy to the resonator's area. Correspondingly, an element of the acoustic mirror, e.g. a mirror layer, establishes at least one element of the first functional structure. For example an electrode of the active part of the resonator establishes an element of the second functional structure.

Acoustic mirrors typically comprise a plurality of two or more layers with different acoustic impedances. At interfaces between layers of different acoustic impedances an acoustic wave is at least partially reflected. A plurality of correspondingly stacked mirrors establishes a Bragg mirror to confine the acoustic energy to the active area of the resonator arranged above the mirror. Providing the mirror's layered elements at a specific location of the electro acoustic component locally disturbs the symmetry of the layer construction of the electro acoustic component. As an unwanted effect, it is possible that a polishing step locally removes more material at the mirror's environment compared to the place of the acoustic mirror itself. Thus, such a polishing step would result in a non-plane top surface with a local elevation at the place of the acoustic mirror. Near structured regions the step height is very low, and at the unstructured areas it can reach more than 100 nm, which can causes a problem with subsequent layers. Subsequent steps, e.g. of providing material for further functional structures, e.g. the bottom element of a BAW resonator in the first layer stack and a metallization used to contact an external circuit environment in the second layer stack, would have different vertical positions. A further step of depositing a dielectric material in the first layer stack and in the second layer stack may cause a different thickness of the dielectric material at the place of the acoustic mirror compared to the place of the structure that should allow a contact to the external circuit environment. In a further subsequent step of removing material of the dielectric material, the different thicknesses could cause material of the dielectric material to remain on the electrode structure such that a non-ideal contact to the external circuit environment would be obtained.

However, by providing the raising structure, the metallization—as the third functional structure—for contacting the external circuit environment and a bottom electrode—as the second functional structure—of a BAW resonator would be vertically levelled and no additional dielectric material would remain on the third functional structure such that a good electric contact to the external circuit environment can be obtained.

The phrase “dummy acoustic mirror”, correspondingly, denotes an acoustic mirror that acts as the raising structure because it results in a local elevation at the second layer stack, too. However, the dummy acoustic mirror is not needed for acoustic reasons in the second layer stack of the present electro acoustic component.

Correspondingly, it is possible that the third functional structure comprises an element of an electrical connection, e.g. an electrical connection to an external circuit environment.

It is possible and/or preferred that the first functional structure and the raising structure have the same height.

A common height for the first functional structure and the raising structure, preferably together with a same vertical level of the first functional structure and the raising structure, improves provision of a common level of the top portion of the first functional structure and the raising structure such that providing a common vertical position of the second functional structure and of the third functional structure is simplified.

Further, it is possible and/or preferred that the first functional structure and the raising structure have the same layer construction.

Thus, it is possible that the first functional structure and the raising structure have the same number of layers. The thicknesses and the materials of corresponding layers of the first functional structure and the raising structure can also be equal.

It is possible that the first layer stack comprises a BAW resonator.

Further, it is possible that the second layer stack comprises a dummy acoustic mirror and an electrical connection to an external circuit environment. Further, it is possible that the first functional structure is an SMR-type BAW resonator (SMR=solidly mounted resonator). The second functional structure is the active element of the SMR-type BAW resonator. The raising structure is a dummy acoustic mirror of an SMR-type BAW resonator and the third functional structure is a bump connection that may comprise a solder bump electrically connected to an external circuit environment or a solder bump that has not yet been electrically connected to an external circuit environment where the bump connection can comprise further layers, e.g. an UBM (under bump metallurgy) layer, an adhesion layer or the like.

Although it is possible that the raising structure provides an acoustic functionality that is not necessarily needed at this specific location, it is possible that one or several elements of the raising structure provide an electrical functionality. An electric functionality can be an electrical shielding or a protection against ESD searches (ESD=electrostatic discharge) and the like.

Specifically, when the raising structure comprises a plurality of mirror layers a good electrostatic shielding can be provided. Further, additional circuit elements of the electro acoustic components such as inductance elements, capacitance elements and/or resistance elements can be elements of the raising structure. Thus, the raising structure not only improves electrical connection to an external circuit environment but also enhances signal quality and miniaturization.

An RF filter comprises an electro acoustic component, e.g. as described above. Further, the RF filter can comprise one or more additional electro acoustic resonators that can be electrically connected to the component as described above.

The RF filter can be the filter of a mobile communication device, e.g. of a wireless terminal. Specifically, the filter can be a filter of a frontend circuit of a corresponding device.

Further, such filters can be used to establish a multiplexer, e.g. a duplexer.

Such a filter can have a ladder-type like circuit topology or a lattice-type like circuit topology. In a ladder-type like circuit topology two or more series resonators are electrically connected in series in a signal path. Parallel paths comprise parallel resonators and electrically connect the signal path to ground.

A method of manufacturing an electro acoustic component, e.g. as described above, comprises the steps of:
providing a carrier substrate,
arranging a first functional structure and a raising structure on or above the carrier substrate,
arranging a second functional structure on or above the first functional structure,
arranging a third functional structure on or above the raising structure at the vertical level of the second functional structure.

Further, a method can comprise the step of at least partially removing material of an intermediate layer below the third functional structure.

Thus, an electro acoustic resonator with an improved performance, specifically with an improved interconnection to an external circuit environment is provided.

For example an implementation of a dummy structure in a layer below a layer of a material that is subject to a material removal step, e.g. a CMP under polish step provides improved electrical connection and avoids problems with the connectivity to the external circuit environment.

The carrier substrate can comprise or consist of silicon.

Mirror layers, e.g. of high acoustic impedance, can comprise or consist of tungsten (W). Layers of the acoustic mirror of a low acoustic impedance can comprise or consist of a silicon oxide, e.g. a silicon dioxide. A piezoelectric material between two electrode layers of the active region of the resonator can comprise or consist of aluminium nitride or scandium-doped aluminium nitride. Electrode layers of the active structure of the resonator can comprise or consist of tungsten, aluminium, gold, silver, copper or alloys thereof.

Central aspects, working principles and details of preferred embodiments are shown in the accompanying schematic figures.

In the figures:

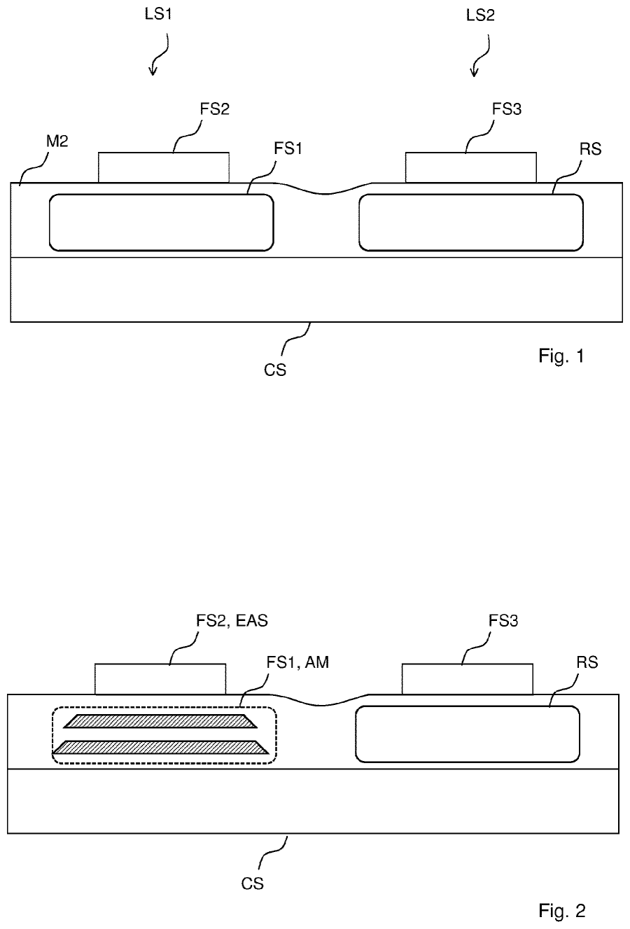

FIG. 1 shows a cross-section of a corresponding component;

FIG. 2 shows an acoustic mirror as the first functional structure;

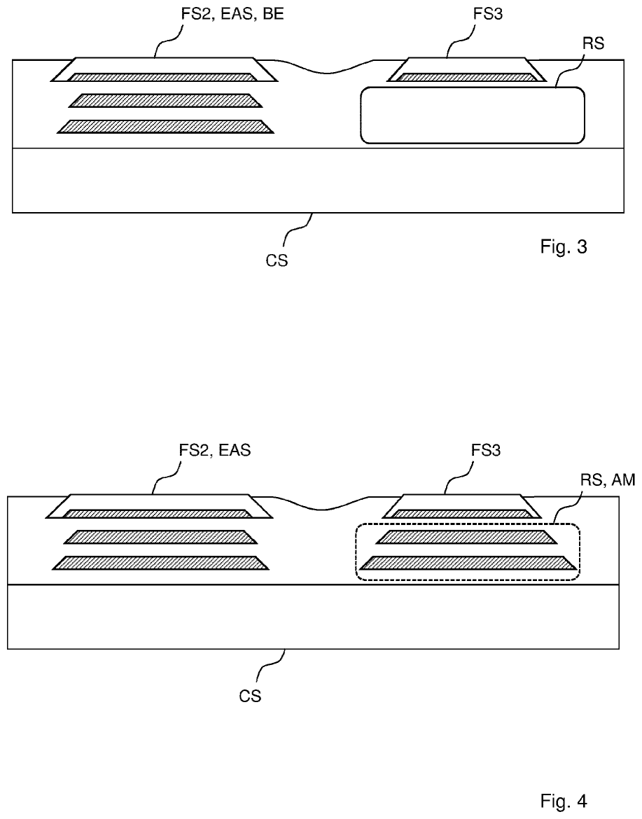

FIG. 3 shows metallization structures for the second and the third functional structures;

FIG. 4 shows a dummy acoustic mirror as the raising structure;

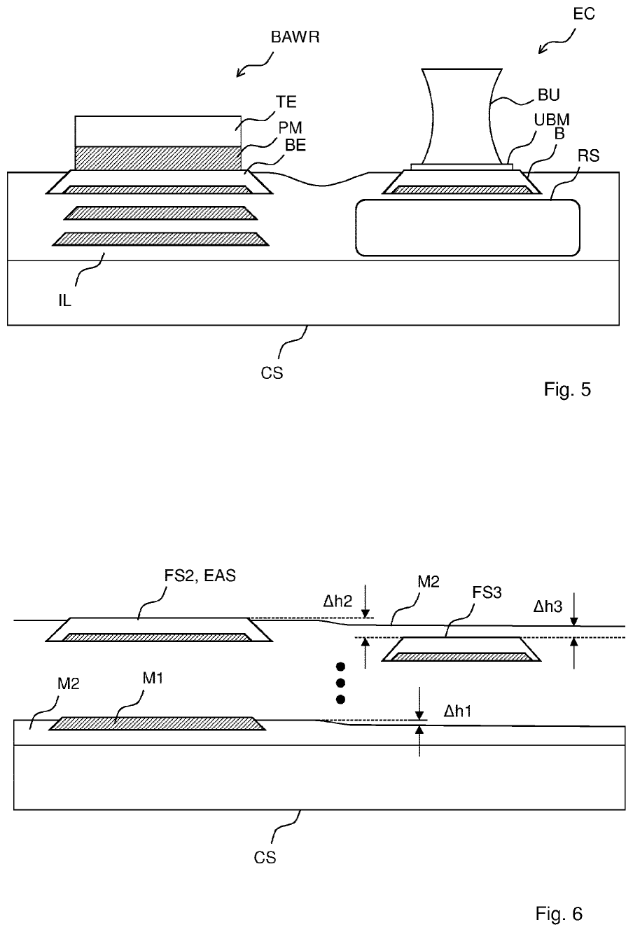

FIG. 5 shows the first layer stack establishing a BAW resonator and the second layer stack establishing an external connection;

FIG. 6 illustrates possible problems with polishing processes and a local disturbance of the component's symmetry; and

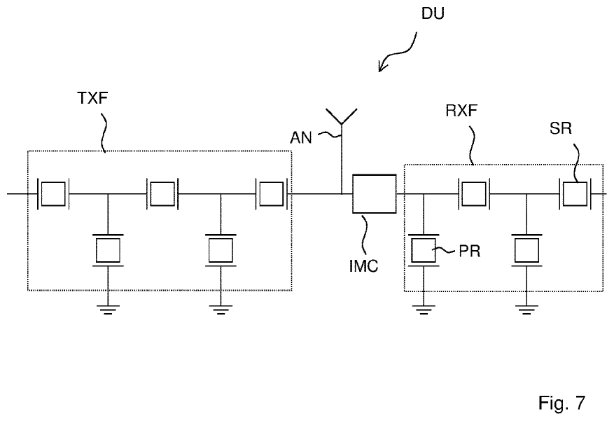

FIG. 7 shows a duplexer comprising two bandpass filters based on a ladder-type like circuit topology.

FIG. 1 shows a cross-section through a schematic electro acoustic component. The component has a carrier substrate CS on which the further structures are arranged. The carrier substrate CS acts as a common carrier for the additional structures of the electro acoustic component. A first layer stack LS1 and a second layer stack LS2 are arranged one next to another on the carrier substrate CS. The first layer stack LS1 comprises a first functional structure FS1 and a second functional structure FS2. The second layer stack LS2 comprises the raising structure RS and the third functional structure FS3. It is possible that the first functional structure FS1 and the raising structure RS are embedded in a matrix material. The provision of the raising structure RS allows to provide the second functional structure FS2 at the same vertical position as the third functional structure FS3. Thus, the distance between the carrier substrate CS and the second functional structure FS2 essentially equals the distance between the carrier substrate CS and the third functional structure FS3. The matrix material can have a plane surface. Specifically, the surface of the matrix material can be parallel to the top surface of the carrier substrate CS. However, it is possible that the thickness of the matrix material locally varies. Specifically, it is possible that the vertical level of the matrix material at the position where the first functional structure FS1 is arranged is higher than in an area surrounding the first functional structure FS1. However, by providing the raising structure RS the corresponding height level of the surface of the matrix material essentially equals the height level of the matrix material at the place of the first functional structure FS1.

FIG. 2 shows the possibility of realizing the first functional structure FS1 as an acoustic mirror AM. An acoustic mirror comprises two or more layers. Adjacent layers—with respect to the vertical direction—have different acoustic impedances. Correspondingly, FIG. 2 illustrates an acoustic mirror comprising two layers of high acoustic impedance being embedded in material of a lower acoustic impedance. The material of high acoustic impedance can be tungsten. The matrix material establishing the material of the low acoustic impedance can be realized as a silicon dioxide.

The second functional structure FS2 can be realized as an electro acoustically active structure EAS comprising (not explicitly shown) two electrodes in two electrode layers and a piezoelectric material in a piezoelectric layer sandwiched between the two electrode layers. The electro acoustically active structure excites acoustic waves, the energy of which is confined to the resonating structure due to the acoustic mirror AM acting as a Bragg mirror and reflecting the acoustic energy to prevent energy dissipation in the carrier substrate CS.

FIG. 3 illustrates the possibility of providing the second functional structure FS2 as the bottom electrode (the lower of the two electrodes of a BAW resonator) arranged above the acoustic mirror. The bottom electrode BE establishes the base for further material deposition of the piezoelectric material of the resonator.

In the second layer stack a metallization is provided establishing the third functional structure FS3 that will be the base for the connection structure for electrically connecting the electro acoustic component to an external circuit environment. The bottom electrode BE and the third functional structure FS3 can have the same layer construction, the same layer thickness and the same number of layers and the same layer materials.

FIG. 4 shows the (preferred) possibility of providing the raising structure RS as a structure having the same construction like the acoustic mirror of the first layer stack. Thus, the raising structure RS is provided as an acoustic mirror AM although the position of the raising structure no acoustic functionality is necessary.

However, by realizing the acoustic mirror of the electro acoustic resonator and the raising structure RS as an acoustic mirror such that both mirrors have the same construction, designing and manufacturing of the component is simplified and as the structures of the raising structure can be realized together with the structures of the acoustic mirror of the first layer stack no additional processing steps are needed and a same vertical level for the second functional structure and for the third functional structure can be obtained.

FIG. 3 illustrates the possibility of providing the piezoelectric material PM in a piezoelectric layer and the top electrode TE in a top electrode layer on the bottom electrode BE in the first layer stack to establish a BAW resonator BAWR. In the second layer stack an under bump metallurgy UBM and a bump connection BU are arranged on the base B of the electrical connection EC to an external circuit environment (not shown).

FIG. 6 illustrates the origin of a possible contact problem when no raising structure RS would be provided. To establish the acoustic mirror on the carrier substrate CS in the first layer structure a plurality of interfaces between materials of different acoustic impedances are provided. For example silicon dioxide is used as the material of the low acoustic impedance. Tungsten can be used as the material of the high acoustic impedance. On a layer of silicon oxide material of a tungsten layer is locally applied. Then, the space next to the tungsten element is filled with silicon dioxide to proceed with the matrix element consisting of the silicon dioxide. To have a plane surface for further layer deposition and structuring steps a polishing step is performed. However, during the polishing, e.g. during CMP, the removal rate at a position far from the tungsten element is higher than at a position near the tungsten. Correspondingly, a small vertical offset Δh1 is obtained. If the corresponding steps are repeated to establish the plurality of layers of the acoustic mirror then the plurality of corresponding small vertical steps Δh1 sum up to a vertical offset Δh2. In a last polishing step at the position of the later electrical contact EC, again, more material is removed than at the position of the later BAW resonator. However, a certain amount of matrix material having a height of Δh3 remains above the third functional structure. Especially when the matrix material is a dielectric material, then contacting problems would arise.

Thus, by providing the raising structure RS the vertical level differences Δh1, Δh2 and Δh3 can be prevented and a parallel alignment of the top surfaces of the second functional structure FS2 and of the third functional structure FS3 at the same vertical position can be obtained without unwanted additional dielectric material above the third functional structure FS3.

FIG. 7 illustrates a basic circuit topology of a duplexer DU. The duplexer DU comprises a transmission filter TXF and a reception filter RXF. The transmission filter TXF usually is connected between a transmission port and an antenna port connected to an antenna AN. The reception filter RXF is typically connected between a reception port and the antenna port. The transmission filter TXF and the reception filter RXF base on a ladder-type like circuit topology having a signal path with series resonators SR electrically connected in series between an input port and an output port. Further, parallel paths comprise parallel resonators PR electrically connecting the signal path to a ground potential.

In order to match the frequency-dependent impedances of the reception filter RXF, the transmission filter TXF and/or the antenna, an impedance matching circuit IMC can be connected between the transmission filter TXF and the reception filter RXF, e.g. at the antenna port.

### LIST OF REFERENCE SIGNS

AM: acoustic mirror
AN: antenna
B: base of electric connection
BAWR: BAW resonator
BE: bottom electrode
BU: bump
CS: carrier substrate
DU: duplexer
EAS: electro acoustically active structure
FS1, FS2, FS3: first, second, third functional structure
IMC: impedance matching circuit
LS1, LS2: first, second layer stack
M1: material of high acoustic impedance, e.g. tungsten
M2: matrix material, material of low acoustic impedance, e.g. silicon dioxide
PM: piezoelectric material
PR: parallel resonator
RS: raising structure
RXF: reception filter
SR: series resonator
TE: top electrode
TXF: transmission filter
UBM: under bump metallurgy

1. An electro acoustic component, comprising
a carrier substrate,
a first layer stack on or above the carrier substrate,
a second layer stack on or above the carrier substrate,
wherein
the first layer stack comprises a first functional structure and a second functional structure arranged on or above the first functional structure,
the second layer stack comprises a raising structure and a third functional structure arranged on or above the raising structure,
the raising structure raises the third functional structure to the vertical level of the second functional structure.

2. The electro acoustic component of claim 1, wherein
the first functional structure comprises an element of an acoustic mirror,
the second functional structure comprises an element of an electro acoustic resonator,
the raising structure comprises an element of a dummy acoustic mirror.

3. The electro acoustic component of one of claim 1, wherein
the third functional structure comprises an element of an electrical connection.

4. The electro acoustic component of one of claim 1, wherein the first functional structure and the raising structure have the same height.

5. The electro acoustic component of claim 1, wherein the first functional structure and the raising structure have the same layer construction.

6. The electro acoustic component of claim 1, wherein the first functional structure and the raising structure have the same construction.

7. The electro acoustic component of claim 1, wherein the first layer stack comprises a BAW resonator.

8. The electro acoustic component of claim 1, wherein
the first functional structure is an SMR-type BAW resonator,
the second functional structure is the active element of the SMR-type BAW resonator.
the raising structure is a dummy acoustic mirror of an SMR-type BAW resonator and
the third functional structure is a bump connection.

9. The electro acoustic component of claim 1, wherein the raising structure provides an electrical functionality.

10. The electro acoustic component of claim 1, wherein the electro acoustic component is part of an RF filter, the RF filter including one or more additional electro acoustic resonators.

11. A method of manufacturing an electro acoustic component, comprising:
providing a carrier substrate,
arranging a first functional structure and a raising structure on or above the carrier substrate,
arranging a second functional structure on or above the first functional structure, and
arranging a third functional structure on or above the raising structure at the vertical level of the second functional structure.

12. The method of claim 11, further comprising partially removing material of an intermediate layer below the third functional structure.
